(19) United States
(12) Patent Application Publication
(10) Pub. No.: US 2012/0280332 A1
(43) Pub. Date: Nov. 8, 2012

(54) PIXEL STRUCTURE AND METHOD FOR FABRICATING THE SAME

(75) Inventors: Jhen-Yu You, New Taipei City (TW); Chen-Yueh Li, Hsinchu City (TW); Ming-Yan Chen, Hsinchu County (TW)

(73) Assignee: AU OPTRONICS CORPORATION, Hsinchu (TW)

(21) Appl. No.: 13/191,484

(22) Filed: Jul. 27, 2011

(30) Foreign Application Priority Data
May 5, 2011 (TW) 100115764

(51) Int. Cl. H01L 29/78; H01L 21/336

(52) U.S. Cl. 257/408; 438/299; 257/E21.409; 257/E29.266

(57) ABSTRACT

A method for fabricating a pixel structure is provided. A patterned semiconductor layer including a lower electrode, a doped source region, a doped drain region and a channel region is formed on a substrate. A gate dielectric layer is formed on the patterned semiconductor layer. A patterned first metal layer including a gate electrode, a scan line and a common electrode is formed on the gate dielectric layer, wherein the channel region is disposed below the gate electrode. A first dielectric layer and a first passivation layer are sequentially formed on the patterned first metal layer. A patterned second metal layer including a source, a drain and a data line is formed on the first passivation layer, wherein the data line is disposed above the common electrode, and the first dielectric layer and the first passivation layer are disposed between the data line and the common electrode.

### CROSS-REFERENCE TO RELATED APPLICATION

This application claims the priority benefit of Taiwan application serial no. 100115764, filed on May 5, 2011. The entirety of the above-mentioned patent application is hereby incorporated by reference herein and made a part of this specification.

### BACKGROUND OF THE INVENTION

1. Field of the Invention

The invention relates to a pixel structure and a method for fabricating the same, and particularly to a pixel structure having a high aperture ratio and a method for fabricating the same.

2. Description of Related Art

Displays are interface between users and information. At present, flat panel displays have become one of the major trends in display development. The flat panel displays are generally categorized into three major types, namely, an organic electroluminescence display, a plasma display panel, and a thin film transistor liquid crystal display. Since the low temperature polysilicon thin film transistor (LTPS-TFT) has advantages such as thin, light and high resolution, the LTPS-TFT has been adopted in mobile terminal products with demands for light weight and power-saving effect.

Although the LTPS-TFT has the above advantages, the process thereof may cause a taper sidewall of the gate, and therefore the gate dielectric layer subsequently formed on the gate should have a larger thickness, so as to have desired step coverage. However, the gate dielectric layer having the greater thickness reduces storage capacitance. In order to maintain a desired storage capacitance, the area of the conductor which is used to form the storage capacitance has to be increased. However, as the storage capacitance is usually formed in the display region, aperture ratio of the pixel structure is greatly reduced.

### SUMMARY OF THE INVENTION

The invention is directed to a method for fabricating a pixel structure, which reduces the number of the required photomasks and improves the aperture ratio of the pixel structure.

The invention is further directed to a pixel structure having a high aperture ratio.

The invention provides a method for fabricating a pixel structure. A patterned semiconductor layer is forded on a substrate, wherein the patterned semiconductor layer includes a lower electrode, a doped source region, a doped drain region and a channel region, and the lower electrode is electrically connected to the doped drain region. A gate dielectric layer is formed on the patterned semiconductor layer. A patterned first metal layer is Ruined on the gate dielectric layer, wherein the patterned first metal layer includes a gate electrode, a scan line and a common electrode, and the channel region is disposed below the gate electrode. A first dielectric layer is formed on the patterned first metal layer. A first passivation layer is formed on the first dielectric layer. A patterned second metal layer is formed on the first passivation layer, wherein the patterned second metal layer includes a source, a drain and a data line which is electrically connected to the source, the source and the drain are respectively electrically connected to the doped source region and the doped drain region, the data line is disposed above the common electrode, and the first dielectric layer and the first passivation layer are disposed between the data line and the common electrode. A second passivation layer is formed on the patterned second metal layer. A pixel electrode is formed on the second passivation layer, wherein the pixel electrode is electrically connected to the drain.

The invention further provides a pixel structure. The pixel structure includes a patterned semiconductor layer, a gate dielectric layer, a patterned first metal layer, a first dielectric layer, a first passivation layer, a patterned second metal layer, a second passivation layer and a pixel electrode. The patterned semiconductor layer is disposed on a substrate, and includes a lower electrode, a doped source region, a doped drain region and a channel region, wherein the lower electrode is electrically connected to the doped drain region. The gate dielectric layer is disposed on the patterned semiconductor layer. The patterned first metal layer is disposed on the gate dielectric layer, and includes a gate electrode, a scan line and a common electrode, wherein the channel region is disposed below the gate electrode. The first dielectric layer covers the patterned first metal layer. The first passivation layer is disposed on the first dielectric layer. The patterned second metal layer is disposed on the first passivation layer, wherein the patterned second metal layer includes a source, a drain and a data line which is electrically connected to the source, the source and the drain are respectively electrically connected to the doped source region and the doped drain region, the data line is disposed above the common electrode, and the first dielectric layer and the first passivation layer are disposed between the data line and the common electrode. The second passivation layer covers the patterned second metal layer. The pixel electrode is disposed on the second passivation layer and electrically connected to the drain.

Based on the above, in the method for fabricating the pixel structure, the common electrode is disposed below the data line, the dielectric layer and the passivation layer are disposed between the common electrode and the data line, and the storage capacitance is formed between the common electrode and the data line. Therefore, the pixel structure has a desired storage capacitance and a high aperture ratio, and parasitic capacitance is prevented from forming between the common electrode and the data line. Moreover, the method for fabricating the pixel structure maintains the advantage of use of six photomasks, so as to simplify the manufacturing process and reduce the manufacturing cost.

In order to make the aforementioned and other features and advantages of the invention more comprehensible, embodiments accompanying figures are described in detail below.

### BRIEF DESCRIPTION OF THE DRAWINGS

The accompanying drawings constituting a part of this specification are incorporated herein to provide a further understanding of the invention. Here, the drawings illustrate embodiments of the invention and, together with the description, serve to explain the principles of the invention.

FIGS. 1A to 1E are schematic top views illustrating a method for fabricating a pixel structure according to an embodiment of the invention.

FIGS. 2A to 2H are schematic cross-sectional views taken along a line I-I′ and a line II-II′ in FIGS. 1A to 1E.

FIG. 3A is a schematic top view of a pixel structure according to an embodiment of the invention.

FIG. 3B is a schematic cross-sectional view taken along a line I-I′ and a line II-II′ in FIG. 3A.

### DESCRIPTION OF EMBODIMENTS

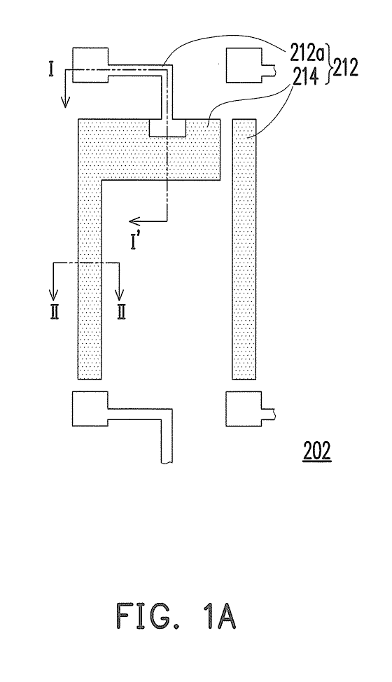

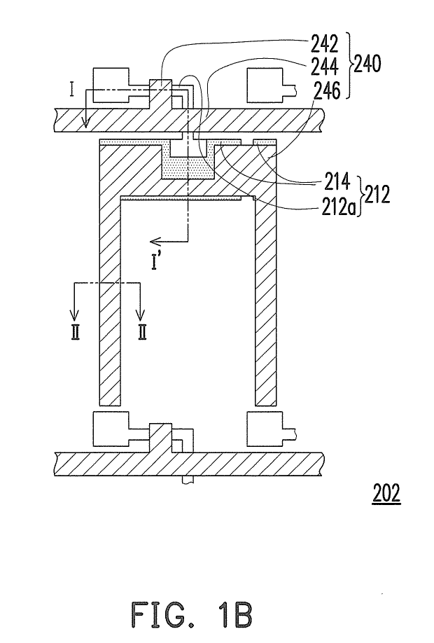

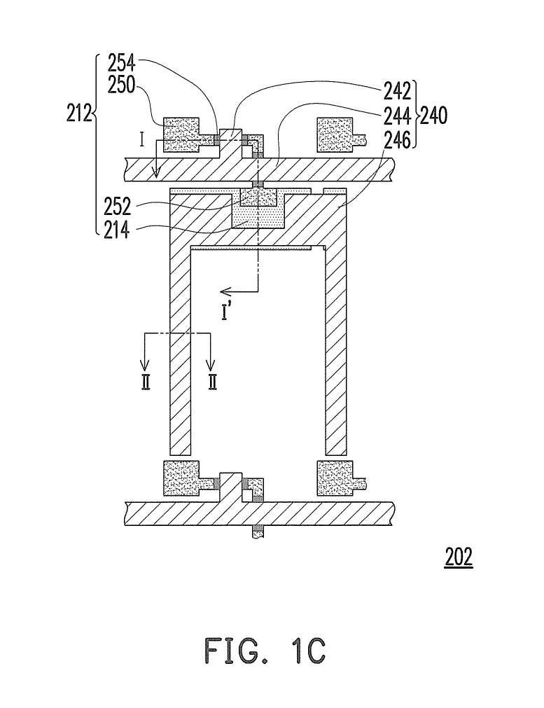

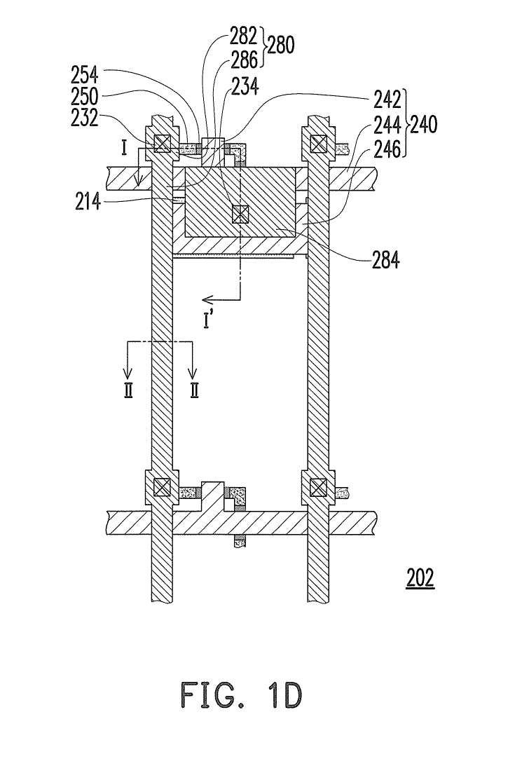

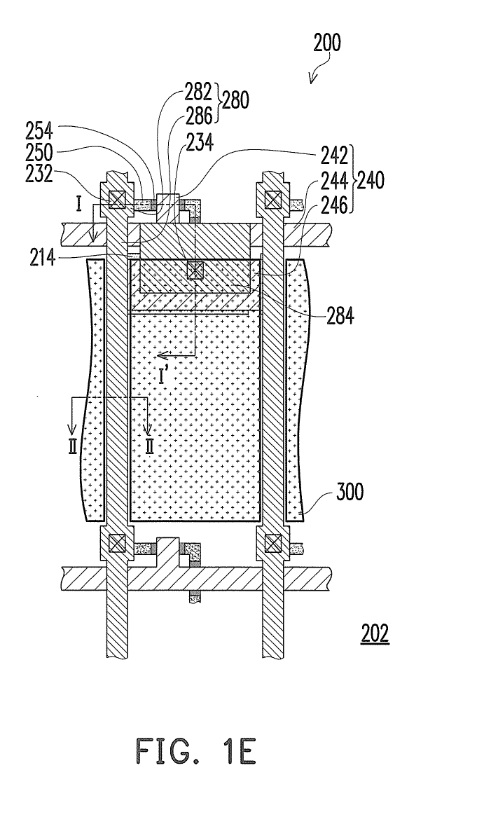

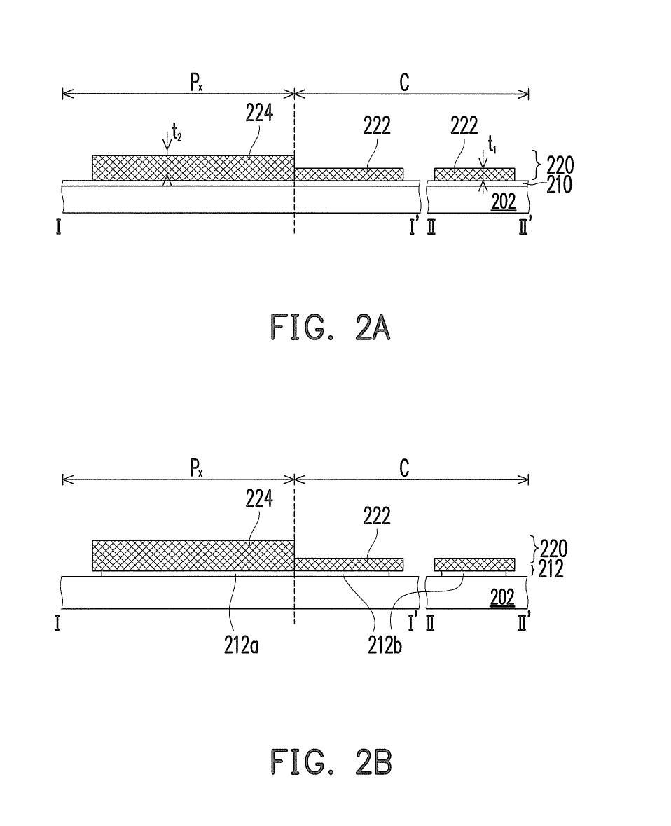

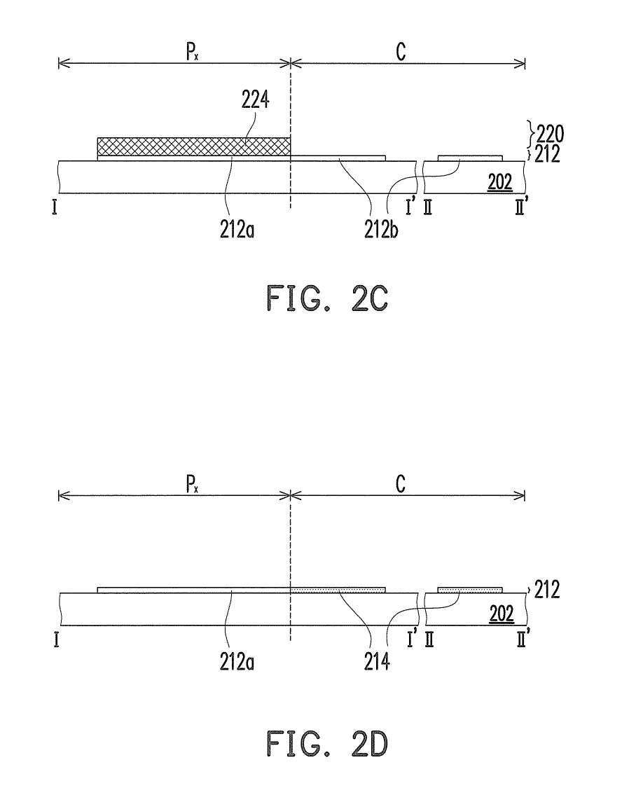

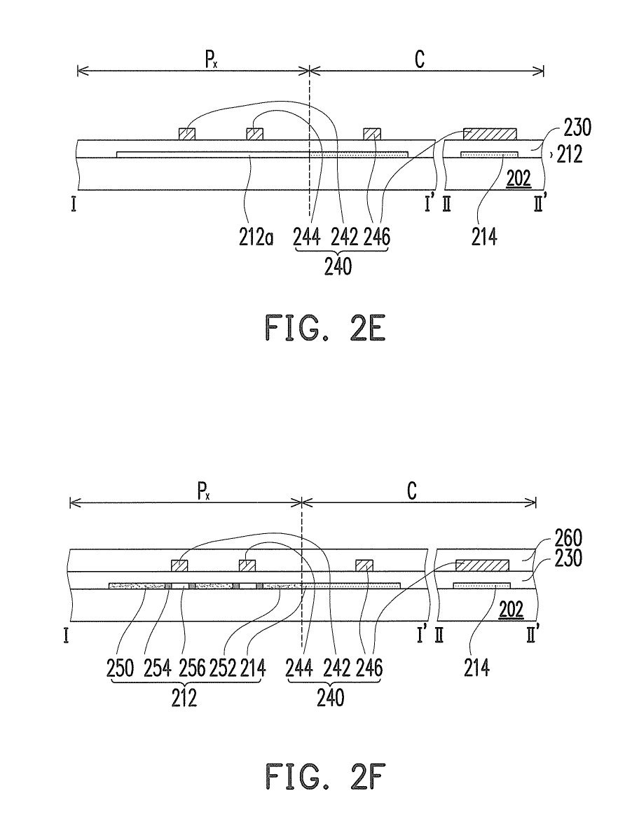

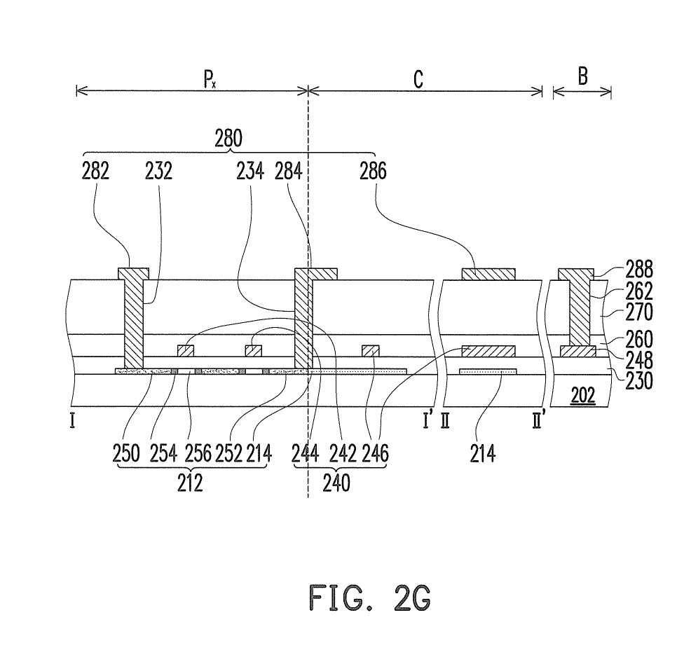

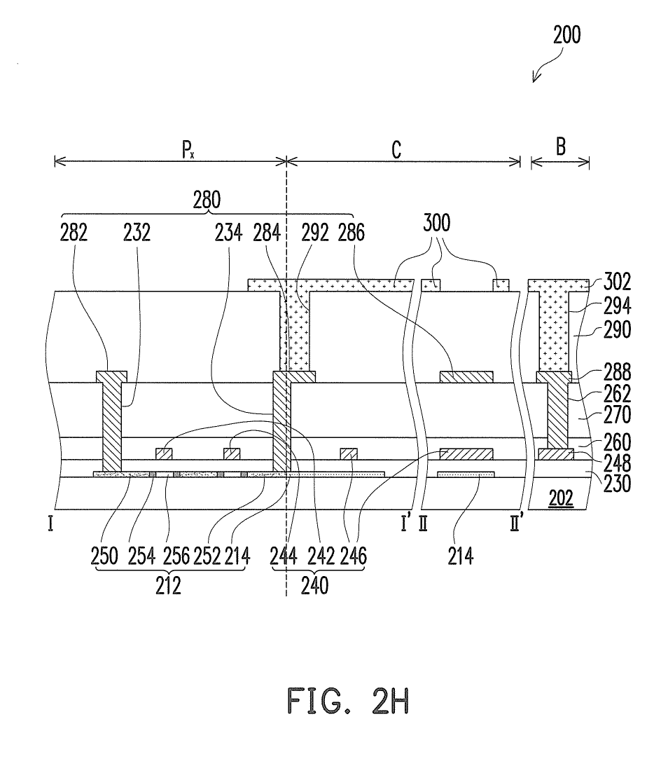

FIGS. 1A to 1E are schematic top views illustrating a method for fabricating a pixel structure according to an embodiment of the invention, and FIGS. 2A to 2H are schematic cross-sectional views taken along a line I-I′ and a line II-II′ in FIGS. 1A to 1E. Referring to FIG. 1A, first, a patterned semiconductor layer 212 is formed on a substrate 202, and a doping process is performed on a portion of the patterned semiconductor layer 212. In this embodiment, the procedure of this step is shown in FIGS. 2A to 2D. First, a semiconductor material layer 210 is formed on a substrate 202. In this embodiment, the substrate 202 has a pixel region Px and a capacitor region C. Particularly, the active device subsequently formed in the pixel region Px is an n-type polysilicon thin film transistor, for example. However, in another embodiment, the active device subsequently formed in the pixel region Px can be a p-type polysilicon thin film transistor. The substrate 202 can be made of glass, quartz, organic polymer, or metal. The semiconductor material layer 210 can be a polysilicon layer, for example. A method of forming the semiconductor material layer 210 includes depositing an amorphous silicon layer, and followed by performing a laser annealing process to the amorphous silicon layer to transform the amorphous silicon layer into a polysilicon layer. In an embodiment (not shown), a buffer layer can be further formed between the substrate 202 and the semiconductor material layer 210. It is noted that, when a first-type thin film transistor (i.e., an n-type thin film transistor) as an active device is formed in the pixel region Px, a second-type thin film transistor (i.e., a p-type thin film transistor) can also be formed in the periphery region (not shown), which is well known to the one skilled in the art, and the detailed description is omitted in this embodiment.

Then, a first photoresist layer 220 is formed on the semiconductor material layer 210, wherein the first photoresist layer 220 includes a lower electrode photoresist pattern 222 having a first thickness t1 and a first photoresist block 224 having a second thickness t2, and the first thickness t1 is smaller than the second thickness t2. In this embodiment, the first photoresist block 224 is disposed above the semiconductor material layer 210 in the pixel region Px, and the lower electrode photoresist pattern 222 is disposed above the semiconductor material layer 210 in the capacitor region C. A method of forming the first photoresist layer 220 is coating a photoresist material layer, and followed by performing a photolithography process on the photoresist material layer with use of a gray scale mask or a halftone mask to pattern the photoresist material layer.

Referring to FIG. 2B, next, an etching process is performed on the semiconductor material layer 210 with use of the first photoresist layer 220 as a mask, so as to form a patterned semiconductor layer 212, wherein the patterned semiconductor layer 212 includes a first semiconductor pattern 212a disposed in the pixel region Px and a second semiconductor pattern 212b disposed in the capacitor region C. In this embodiment, after the step of performing the patterning process (i.e., the etching process), further includes performing a lateral etching process on the first semiconductor pattern 212a and the second semiconductor pattern 212b. As such, the sidewalls of the first semiconductor pattern 212a and the second semiconductor pattern 212b are etched, so that widths of the first semiconductor pattern 212a and the second semiconductor pattern 212b are reduced. In other words, the sidewalls of the first semiconductor pattern 212a and the second semiconductor pattern 212b draw back with respect to the sidewalls of the first photoresist layer 220.

Referring to FIG. 2C, afterwards, a thickness of the first photoresist layer 220 is reduced, so as to remove the lower electrode photoresist pattern 222 and expose the second semiconductor pattern 212b. In this embodiment, a method of reducing the thickness of the first photoresist layer 220 is performing a photoresist ashing process, thereby removing the lower electrode photoresist pattern 222 of the first photoresist layer 220 and a portion of the first photoresist block 224, so as to expose the second semiconductor pattern 212b. It is noted that, since the process of reducing the thickness of the first photoresist layer 220 also removes a portion of the sidewall of the first photoresist layer 220, the sidewall of the remained first photoresist block 224 is substantially aligned with the sidewall of the first semiconductor pattern 212a, so that the remained first photoresist block 224 covers the first semiconductor pattern 212a.

Referring to FIGS. 1A and 2D, then, a first type ion doping process is performed on the patterned semiconductor layer 212 with use of the remained first photoresist block 224 as a mask, so as to form the lower electrode 214. Next, the remained first photoresist block 224 is removed. In this embodiment, the first type ion doping process is a p-type ion doping process. Therefore, the lower electrode 214 is formed as a p type-doped polysilicon pattern after performing the first type ion doping process.

Referring to FIGS. 1B and 2E, next, a gate dielectric layer 230 is formed on the patterned semiconductor layer 212. In this embodiment, a method of forming the gate dielectric layer 230 is the CVD process or the PVD process, for example. A material of the gate dielectric layer 230 is, for example, silicon oxide, silicon nitride, silicon oxynitride or other suitable materials. A ratio of a thickness of the gate dielectric layer 230 and a thickness of the lower electrode 214 ranges from 2 to 3, for example.

A patterned first metal layer 240 is then formed on the gate dielectric layer 230, wherein the patterned first metal layer 240 includes a gate electrode 242, a scan line 244 and a common electrode 246. In this embodiment, the procedure of this step includes the followings. First, a first metal layer is formed (not shown) on the gate dielectric layer 230. A second photoresist layer (not shown) is then formed on the first metal layer. By using the second photoresist layer as a mask, an etching process is performed on the first metal layer, so as to form a patterned first metal layer 240.

Referring to FIGS. 1C and 2F, thereafter, a doped source region 250 and a doped drain region 252 are formed in the first semiconductor pattern 212a. In detail, a second type ion heavily doping process is performed on the patterned semiconductor layer 212 with use of the second photoresist layer as a mask. In this embodiment, the second type ion heavily doping process is an n-type heavily doping process. Therefore, the doped source region 250 and the doped drain region 252 are n type-doped regions.

Moreover, this step further includes reducing a width of the second photoresist layer, and removing the first metal layer which is not covered by the second photoresist layer. Then, a second type ion lightly doping process is performed on the first semiconductor pattern 212a with use of the remained second photoresist layer as a mask, so as to form the lightly doped regions 254. In this embodiment, the second type ion lightly doping process is, for example, an n-type lightly doping process. As such, after performing the second type ion lightly doping process, the channel region 256 is formed below the gate electrode 242, and the lightly doped regions 254 are respectively formed between the channel region 256 and the doped source region 250 and between the channel region 256 and the doped drain region 252. The lightly doped regions 254 are n-type lightly doped regions, for example.

Afterwards, a first dielectric layer 260 is formed on the patterned first metal layer 240. In this embodiment, a method of forming the first dielectric layer 260 is the CVD process or the PVD process, for example. A material of the first dielectric layer 260 is, for example, silicon oxide, silicon nitride, silicon oxynitride or other suitable materials.

Referring to FIG. 2G, a first passivation layer 270 is formed on the first dielectric layer 260. A method of forming the first passivation layer 270 is spin coating, for example, and thus an organic material can be formed on the first dielectric layer 260. The organic material is acrylic resin or other suitable materials, for example.

Referring to FIGS. 1D and 2G, a patterned second metal layer 280 is formed on the first passivation layer 270, wherein the patterned second metal layer 280 includes a source 282, a drain 284 and a data line 286 which is electrically connected to the source 282, the source 282 and the drain 284 are respectively electrically connected to the doped source region 250 and the doped drain region 252, the data line 286 is disposed above the common electrode 246, and the first dielectric layer 260 and the first passivation layer 270 are disposed between the data line 286 and the common electrode 246. In this embodiment, before forming the patterned second metal layer 280, a first opening 232 and a second opening 234 are formed in the gate dielectric layer 230, the first dielectric layer 260 and the first passivation layer 270, and the source 282 and the drain 284 are then formed in the first opening 232 and the second opening 234, respectively. As such, the source 282 is electrically connected to the doped source region 250 through the first opening 232, and the drain 284 is electrically connected to the doped drain region 252 through the second opening 234. It is noted that, as shown in FIG. 2G, the patterned second metal layer 280 further includes a bonding pad 288 disposed in the periphery region B, and the bonding pad 288 is electrically connected to a periphery pattern 248 of the patterned first metal layer 240 through an opening 262 formed in the first dielectric layer 260 and the first passivation layer 270.

Referring to FIGS. 1E and 2H, then, a second passivation layer 290 is formed on the patterned second metal layer 280. Next, a pixel electrode 300 is formed on the second passivation layer 290, wherein the pixel electrode 300 is electrically connected to the drain 284. In detail, a third opening 292 is formed in the second passivation layer 290, and then the pixel electrode 300 is formed on the second passivation layer 290, wherein a portion of the pixel electrode 300 is formed in the third opening 292, so that the pixel electrode 300 is electrically connected to the drain 284 through the third opening 292. In this embodiment, a method of forming the second passivation layer 290 is the CVD process or the PVD process, for example. A material of the second passivation layer 290 is, for example, silicon oxide, silicon nitride, silicon oxynitride or other suitable materials. Particularly, a method of forming the second passivation layer 290 can be spin coating, and a material of the second passivation layer 290 can be an organic material such as acrylic resin or other suitable materials. In addition, as shown in FIG. 2H, a conductive pattern 302 is formed on the bonding pad 288 disposed in the periphery region B, for example. A material of the conductive pattern 302 can be the same as that of the pixel electrode 300, and the conductive pattern 302 can be electrically connected to the bonding pad 288 through the opening 294 formed in the second passivation layer 290.

In this embodiment, the pixel structure 200 includes the patterned semiconductor layer 212, the gate dielectric layer 230, the patterned first metal layer 240, the first dielectric layer 260, the first passivation layer 270, the patterned second metal layer 280, the second passivation layer 290 and the pixel electrode 300. The patterned semiconductor layer 212 is disposed on the substrate 202, and includes the lower electrode 214, the doped source region 250, the doped drain region 252 and the channel region 256, wherein the lower electrode 214 is electrically connected to the doped drain region 252. The gate dielectric layer 230 is disposed on the patterned semiconductor layer 212. In this embodiment, the lightly doped regions 254 are respectively formed between the doped source region 250 and the channel region 256 and between the doped drain region 252 and the channel region 256.

The patterned first metal layer 240 is disposed on the gate dielectric layer 230, and includes the gate electrode 242, the scan line 244 and the common electrode 246, wherein the channel region 256 is disposed below the gate electrode 242. The first dielectric layer 260 covers the patterned first metal layer 240. The first passivation layer 270 is disposed on the first dielectric layer 260. The patterned second metal layer 280 is disposed on the first passivation layer 270, wherein the patterned second metal layer 280 includes the source 282, the drain 284 and the data line 286 which is electrically connected to the source 282, the source 282 and the drain 284 are respectively electrically connected to the doped source region 250 and the doped drain region 252, the data line 286 is disposed above the common electrode 246, and the first dielectric layer 260 and the first passivation layer 270 are disposed between the data line 286 and the common electrode 246. The second passivation layer 290 covers the patterned second metal layer 280. The pixel electrode 300 is disposed on the second passivation layer 290 and electrically connected to the drain 284.

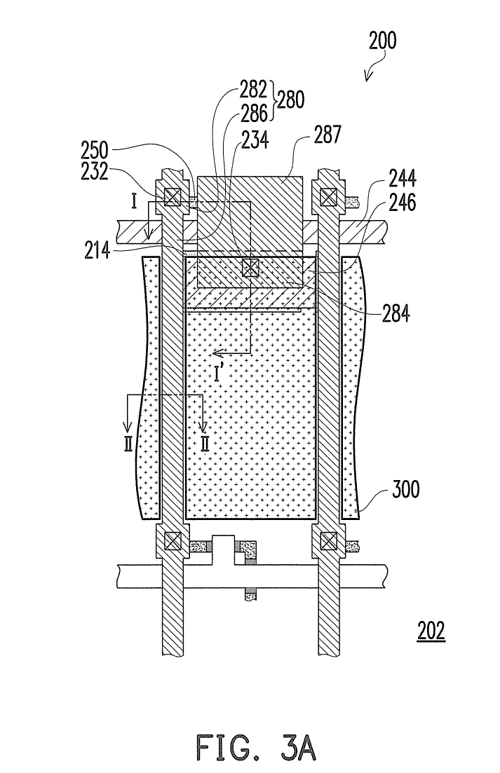

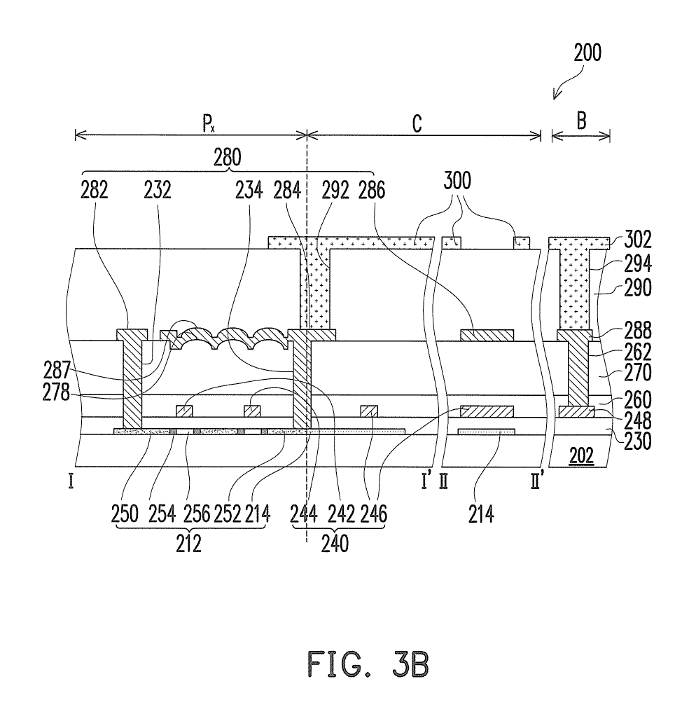

It is noted that, in another embodiment, as shown in FIGS. 3A and 3B, the patterned second metal layer 280 can further include a reflective electrode 287. In detail, a plurality of bumps 278 is formed on a surface of the first passivation layer 270, and the reflective electrode 287 is formed on the bumps 278, for example. Generally, the reflective electrode 287 is disposed overlapping with the patterned first metal layer 240 or the patterned second metal layer 280, and therefore the aperture ratio of the pixel structure 200 is not affected. For example, in this embodiment, the reflective electrode 287 is disposed on the bumps 278 and above and overlapping with the gate 242 and the scan line 244. However, in another embodiment, the reflective electrode 287 can be formed on the first passivation layer 270 which does not have a plurality of bumps 278 formed thereon. In addition, the reflective electrode 287 can be electrically connected to the drain 284 (as shown in FIGS. 3A and 3B) or not (not shown).

Referring to FIGS. 2A and 2B, in the process of forming the first photoresist layer 220 with use of the of a gray scale mask or a halftone mask, the subsequent process of reducing the thickness of the first photoresist layer 220 simultaneously removes a portion of the sidewall of the first photoresist layer 220, and thus the sidewall of the patterned semiconductor layer 212, which is formerly covered by the sidewall of the first photoresist layer 220, is exposed. Therefore, before performing the step of reducing the thickness of the first photoresist layer 220, a lateral etching process is generally performed on the patterned semiconductor layer 212 (including the first and second semiconductor patterns 212a and 212b). However, the lateral etching process causes the taper sidewalls of the first and second semiconductor patterns 212a and 212b, and thus the gate dielectric layer 230 subsequently formed on the gate electrode 242 should have a larger thickness to have desired step coverage. As the common electrode 246 and the lower electrode 214 constitute a storage capacitor Cst, which is used for stabilizing data voltages in the pixel structure, the thicker gate dielectric layer 230 reduces the storage capacitor Cst.

In this embodiment, the common electrode 246 is disposed below the data line 286 and the common electrode 246 and the data line 286 are at least partially overlapped with each other, so that the common electrode 246 can have a larger area and the aperture ratio of the pixel structure is not affected. As such, the storage capacitor Cst constituted by the common electrode 246 and the lower electrode 214 is greatly increased, so as to compensate the possible loss of the storage capacitance caused by the thicker gate dielectric layer 230. In addition, the first dielectric layer 260 and the first passivation layer 270 disposed between the common electrode 246 and the data line 286 can prevent the parasitic capacitance formed in the overlapping region of the common electrode 246 and the data line 286. In other words, in the embodiment, the common electrode 246 is designed to be disposed below the data line 286 and at least partially overlapped with the data line 286, so that the possible loss of the storage capacitance caused by the thicker gate dielectric layer 230 can be compensated. As such, the method for fabricating the pixel structure of the embodiment maintains the advantage of use of six photomasks, so as to simplify the manufacturing process and reduce the manufacturing cost. Moreover, the pixel structure has a desired storage capacitance and a high aperture ratio.

In light of the foregoing, in the method for fabricating the pixel structure of the invention, the common electrode is disposed below and at least partially overlapped with the data line, and the dielectric layer and the passivation layer are disposed between the common electrode and the data line. As such, the pixel structure has a desired storage capacitance and a high aperture ratio, and the parasitic capacitance formed in the overlapping region of the common electrode and the data line is prevented. Accordingly, the pixel structure has superior device characteristics. Moreover, the method for fabricating the pixel structure can be applied in the existing six-photomask manufacturing process, that is, additional photomask is not required, so as to simplify the manufacturing process and reduce the manufacturing cost.

It will be apparent to those skilled in the art that various modifications and variations can be made to the structure of the invention without departing from the scope or spirit of the invention. In view of the foregoing, it is intended that the invention cover modifications and variations of this invention provided they fall within the scope of the following claims and their equivalents.

What is claimed is:

1. A method for fabricating a pixel structure, the method comprising:
forming a patterned semiconductor layer on a substrate, wherein the patterned semiconductor layer includes a lower electrode, a doped source region, a doped drain region and a channel region, and the lower electrode is electrically connected to the doped drain region;
forming a gate dielectric layer on the patterned semiconductor layer;
forming a patterned first metal layer on the gate dielectric layer, wherein the patterned first metal layer includes a gate electrode, a scan line and a common electrode, and the channel region is disposed below the gate electrode;
forming a first dielectric layer on the patterned first metal layer;
forming a first passivation layer on the first dielectric layer;
forming a patterned second metal layer on the first passivation layer, wherein the patterned second metal layer includes a source, a drain and a data line electrically connected to the source, the source and the drain are respectively electrically connected to the doped source region and the doped drain region, the data line is disposed above the common electrode, and the first dielectric layer and the first passivation layer are disposed between the data line and the common electrode;
forming a second passivation layer on the patterned second metal layer; and
forming a pixel electrode on the second passivation layer, wherein the pixel electrode is electrically connected to the drain.

2. The method as claimed in claim 1, wherein a method of forming the lower electrode comprises:
forming a semiconductor material layer on the substrate;
forming a first photoresist layer on the semiconductor material layer, wherein the first photoresist layer includes a lower electrode photoresist pattern having a first thickness and a first photoresist block having a second thickness, and the first thickness is smaller than the second thickness;
performing an etching process on the semiconductor material layer with use of the first photoresist layer as a mask, so as to form a patterned semiconductor layer;
reducing a thickness of the first photoresist layer so as to remove the lower electrode photoresist pattern and expose a portion of the patterned semiconductor layer; and
performing an ion doping process on the patterned semiconductor layer with use of the remained first photoresist block as a mask, so as to form the lower electrode.

3. The method as claimed in claim 2, wherein a method of forming the first photoresist layer comprises an exposure and development process with use of a halftone mask.

4. The method as claimed in claim 2, after the step of performing an etching process on the semiconductor material layer with use of the first photoresist layer as a mask, further comprising performing a lateral etching process on the semiconductor material layer.

5. The method as claimed in claim 1, further comprising forming lightly doped regions respectively located between the doped source region and the channel region and between the doped drain region and the channel region.

6. The method as claimed in claim 5, wherein a method of forming the patterned semiconductor layer, the gate dielectric layer and the patterned first metal layer comprises:
forming a semiconductor material layer on the substrate;
forming a first photoresist layer on the semiconductor material layer, wherein the first photoresist layer includes a lower electrode photoresist pattern having a first thickness and a first photoresist block having a second thickness, and the first thickness is smaller than the second thickness;
performing an etching process on the semiconductor material layer with use of the first photoresist layer as a mask, so as to form a patterned semiconductor layer;
reducing a thickness of the first photoresist layer so as to remove the lower electrode photoresist pattern and expose a portion of the patterned semiconductor layer;
performing a first type ion doping process on the patterned semiconductor layer with use of the remained first photoresist block as a mask, so as to form the lower electrode;
removing the remained first photoresist block;
forming the gate dielectric layer entirely on the substrate;
forming a first metal layer on the gate dielectric layer;
forming a second photoresist layer on the first metal layer;
performing an etching process on the first metal layer with use of the second photoresist layer as a mask;
performing a second type ion heavily doping process on the patterned semiconductor layer with use of the second photoresist layer as a mask, so as to form the doped source region and the doped drain region;
reducing a width of the second photoresist layer, and removing the first metal layer which is not covered by the second photoresist layer; and
performing a second type ion lightly doping process on the patterned semiconductor layer with use of the remained second photoresist layer as a mask, so as to form the lightly doped regions.

7. The method as claimed in claim 1, further comprising forming a first opening and a second opening in the gate dielectric layer, the first dielectric layer and the first passivation layer, wherein the source is electrically connected to the doped source region through the first opening, and the drain is electrically connected to the doped drain region through the second opening.

8. The method as claimed in claim 1, further comprising forming a third opening in the second passivation layer, wherein the pixel electrode is connected to the drain through the third opening.

9. The method as claimed in claim 1, wherein the patterned second metal layer further comprises a reflective electrode.

10. The method as claimed in claim 9, further comprising forming a plurality of bumps on a surface of the first passivation layer, wherein the reflective electrode is formed on the bumps.

11. The method as claimed in claim 1, wherein a material of the first passivation layer comprises an organic material.

12. The method as claimed in claim 1, wherein a ratio of a thickness of the gate dielectric layer and a thickness of the lower electrode ranges from 2 to 3.

13. A pixel structure, comprising:
a patterned semiconductor layer, disposed on a substrate and including a lower electrode, a doped source region, a doped drain region and a channel region, wherein the lower electrode is electrically connected to the doped drain region;
a gate dielectric layer, disposed on the patterned semiconductor layer;
a patterned first metal layer, disposed on the gate dielectric layer and including a gate electrode, a scan line and a common electrode, wherein the channel region is disposed below the gate electrode;
a first dielectric layer, covering the patterned first metal layer;
a first passivation layer, disposed on the first dielectric layer;
a patterned second metal layer, disposed on the first passivation layer and including a source, a drain and a data line electrically connected to the source, wherein the source and the drain are respectively electrically connected to the doped source region and the doped drain region, the data line is disposed above the common electrode, and the first dielectric layer and the first passivation layer are disposed between the data line and the common electrode;
a second passivation layer, covering the patterned second metal layer; and
a pixel electrode, disposed on the second passivation layer and electrically connected to the drain.

14. The pixel structure as claimed in claim 13, further comprising lightly doped regions respectively located between the doped source region and the channel region and between the doped drain region and the channel region.

15. The pixel structure as claimed in claim 13, further comprising a first opening and a second opening disposed in the gate dielectric layer, the first dielectric layer and the first passivation layer, wherein the source is electrically connected to the doped source region through the first opening, and the drain is electrically connected to the doped drain region through the second opening.

16. The pixel structure as claimed in claim 13, further comprising a third opening disposed in the second passivation layer, wherein the pixel electrode is connected to the drain through the third opening.

17. The pixel structure as claimed in claim 13, wherein the patterned second metal layer further comprises a reflective electrode.

18. The pixel structure as claimed in claim 17, further comprising a plurality of bumps disposed on a surface of the first passivation layer, wherein the reflective electrode is disposed on the bumps.

19. The pixel structure as claimed in claim 13, wherein a material of the first passivation layer comprises an organic material.

20. The pixel structure as claimed in claim 13, wherein a ratio of a thickness of the gate dielectric layer and a thickness of the lower electrode ranges from 2 to 3.
